(19) United States
(12) Patent Application Publication
(10) Pub. No.: US 2026/0042946 A1
(43) Pub. Date: Feb. 12, 2026

(54) POLISHING SLURRY AND METHOD FOR MANUFACTURING DISPLAY DEVICE USING THE SAME

(71) Applicants: Samsung Display Co., Ltd., Yongin-Si (KR); IUCF-HYU (Industry-University Cooperation Foundation Hanyang University), Seoul (KR)

(72) Inventors: Sukyeong SHIN, Yongin-si (KR); Jea Gun PARK, Seoul (KR); Joon-Hwa BAE, Yongin-si (KR); Hee Sung YANG, Yongin-si (KR); Woo Jin CHO, Yongin-si (KR)

(21) Appl. No.: 19/270,510

(22) Filed: Jul. 16, 2025

(30) Foreign Application Priority Data
Aug. 12, 2024 (KR) 10-2024-0107861

(51) Int. Cl. C09K 3/14; B24B 37/04; H01L 21/321; H10K 71/60

(52) U.S. Cl. CPC C09K 3/1463; B24B 37/044; H01L 21/3212; H10K 71/60

(57) ABSTRACT

In an embodiment, a polishing slurry comprises polishing particles, an oxidizer, and a zwitterionic compound. A method for manufacturing a display device using a polishing slurry according to an embodiment includes preparing a substrate, forming a transistor on the substrate, forming an insulating layer on the transistor, patterning the insulating layer to form a trench, depositing metal in the trench on the insulating layer to form a first electrode formation layer, polishing the first electrode formation layer using a polishing slurry to form a first electrode, forming a light emitting layer on the first electrode, and forming a second electrode on the light emitting layer, wherein the first electrode is electrically connected to the transistor, and the polishing slurry includes polishing particles, an oxidizer, and a zwitterionic compound.

### CROSS-REFERENCE TO RELATED APPLICATION

This application claims priority to and the benefit of Korean Patent Application No. 10-2024-0107861 filed at the Korean Intellectual Property Office on Aug. 12, 2024, the entire contents of which are incorporated herein by reference.

### BACKGROUND

### (a) Field

The present disclosure relates to a polishing slurry and a method for manufacturing a display device using the same.

### (b) Description of the Related Art

As display devices are developed with higher resolution, the number of wiring layers is increasing, which requires reduction in steps and minimization of resistance. In particular, in a process in which metal wiring and insulating layers are sequentially laminated, surface unevenness of each layer may be transferred to and affect the next layer. To remove the unevenness of the surface, a planarization process is used. The chemical mechanical polishing CMP method is used to planarize the uneven surface. The chemical mechanical polishing CMP is a process of planarizing the surface by providing a polishing slurry containing polishing particles and various compounds and performing a polishing using a polishing pad. Depending on the target to which this CMP process is applied, there is a need to develop an appropriate polishing slurry that may increase polishing speed, improve process efficiency, and reduce thickness when applied to multilayer wiring.

### SUMMARY

Embodiments are intended to provide a polishing slurry having a high polishing rate and for increasing a reflectivity of a silver (Ag) or aluminum (Al) electrode of a display device. Furthermore, the embodiments are intended to provide a method for manufacturing a display device using the aforementioned polishing slurry.

In an embodiment, a polishing slurry comprises polishing particles, an oxidizer, and a zwitterionic compound.

The polishing slurry may polish silver (Ag) or aluminum (Al).

The polishing particles may contain a silicon compound.

The polishing particles may include at least one selected from a group consisting of silica (SiO₂), ceria (CeO₂), zirconia (ZrO₂), and alumina (Al₂O₃).

An amount of the polishing particles may be 0.1 wt % to 5.0 wt % with respect to the total amount of the polishing slurry.

An average particle diameter of the polishing particles may be 50 nm to 700 nm.

The oxidizer may include at least one selected from a group consisting of oxygen (O₂), hydrogen peroxide (H₂O₂), ozone (O₃), PAA(CH₃CO₃H), NaIO₄, H₅IO₆, KIO₄, HOCl, NaCOI, I₂, Cl₂, CuO, PbO₂, MnO₂, HNO₃, KNO₃, F₂, and H₂SO₄.

An amount of the oxidizer may be 0.01 wt % to 5.0 wt %.

The polishing slurry according to an embodiment may have a pH of 3 to 10. The polishing slurry according to an embodiment may further comprise a pH adjuster.

The pH adjuster may include at least one selected from a group consisting of HNO₃, NaOH, KOH, and TMAH (tetramethylammonium hydroxide).

The zwitterionic compound may include at least one selected from a group consisting of alanine, phenylalanine, proline, glycine, histidine, lysine, arginine, threonine, aspartic acid, tryptophan, glutamine, betaine, cocamidopropyl betaine and lauryl propyl betaine.

An amount of the zwitterionic compound may be greater than 0 wt % and less than or equal to 5.0 wt %.

The polishing slurry according to an embodiment may further comprise a corrosion inhibitor.

The corrosion inhibitor may include at least one selected from a group consisting of benzotriazole (BTA), dicyclohexylammonium nitrite (DAN), triethanolamine (TEA), monoethanolamine (MEA), and diethanolamine (DEA).

An amount of the corrosion inhibitor may be greater than 0 wt % and less than or equal to 5.0 wt %.

A method for manufacturing a display device using a polishing slurry according to an embodiment includes preparing a substrate, forming a transistor on the substrate, forming an insulating layer on the transistor, forming a trench by patterning the insulating layer, forming a first electrode formation layer by depositing metal in the trench on the insulating layer, forming a first electrode by polishing the first electrode formation layer using a polishing slurry, forming a light emitting layer on the first electrode, and forming a second electrode on the light emitting layer, wherein the first electrode is electrically connected to the transistor, and the polishing slurry includes polishing particles, an oxidizer, and a zwitterionic compound.

The first electrode may include at least one of silver (Ag) or aluminum (Al).

The polishing slurry may further contain a corrosion inhibitor.

The polishing slurry may further contain a pH adjuster.

When a silver (Ag) or aluminum (Al) electrode of a display device is polished using a polishing slurry according to the present embodiment, the reflectivity of the electrode increases, thereby improving the light efficiency of the display device.

In addition, the polishing slurry according to the present embodiment has a high polishing rate, so that the process time may be shortened.

### BRIEF DESCRIPTION OF THE DRAWINGS

FIG. 1 is a graph measuring a polishing rate and etch rate of a silver film according to an amount of H₅IO₆.

FIG. 2 is a graph measuring absorbance and absorbance reduction according to the amount of H₅IO₆.

FIG. 3 is a graph measuring an electrostatic repulsion between the polishing slurry and the silver film according to the amount of H₅IO₆.

FIG. 4 is a graph measuring the polishing rate and etch rate of a silver film according to an amount of glycine.

FIG. 5 is a graph measuring the electrostatic repulsion between the polishing slurry and the silver film according to the amount of glycine.

FIG. 6 is a graph measuring the polishing rate and etch rate of a silver film according to an amount of BTA.

FIG. 7 is a graph measuring a surface roughness of a silver film according to the amount of BTA.

FIGS. 8, 9, 10 and 11 are data measuring a degree of formation of silver oxide layer according to the amount of H₅IO₆.

FIG. 12 is a cross-sectional view of a display device manufactured using a polishing slurry according to an embodiment.

FIGS. 13, 14, 15, 16, 17, 18 and 19 are process cross-sectional views illustrating a method of manufacturing a display device using a polishing slurry according to an embodiment.

### DETAILED DESCRIPTION

Hereinafter, various embodiments of the present disclosure will be described in detail with reference to the attached drawings so that a person having ordinary skill in the art to which the present disclosure pertains may easily implement the present disclosure. The present disclosure may be embodied in many different forms and is not limited to the embodiments described herein.

In order to clearly explain the present disclosure, parts irrelevant to the description are omitted, and the same reference numerals are used for identical or similar components throughout the specification.

In addition, the size and thickness of each component shown in the drawings are arbitrarily shown for convenience of explanation, so the present disclosure is not necessarily limited to that which is shown. In the drawings, the thicknesses of layers, films, panels, regions, etc., are exaggerated for clarity. And in the drawings, for convenience of explanation, the thickness of some layers and areas is exaggerated.

Also, when it is said that a part, such as a layer, membrane, region, or plate, is “over” or “on” another part, this includes not only cases in which it is “directly over” the other part, but also cases in which there are other parts in between. In contrast, when an element is referred to as being “directly on” another element, there are no intervening elements present. Also, being “above” or “on” a reference part means being located above or below the reference part, and does not necessarily mean being located “above” or “on” it in the opposite direction of gravity.

Additionally, throughout the specification, whenever a part is said to “include” a component, this does not mean that it excludes other components, but rather that it may include other components, unless otherwise specifically stated.

Additionally, throughout the specification, reference to “in a plan view” means when the target portion is viewed from above, and reference to “in a cross-sectional view” means when the target portion is viewed from the side in a cross-section cut vertically.

A polishing slurry according to an embodiment of the present disclosure may include polishing particles, an oxidizer, and a zwitterionic compound, also known as inner salts or dipolar ions. The polishing slurry according to an embodiment may be used for polishing a metal film—for example, a silver (Ag) film or an aluminum (Al) film.

The polishing particles are substances that physically polish a polishing target film. The polishing particles may contain silicon compounds. The polishing particles may include at least one selected from a group consisting of silica (SiO₂), ceria (CeO₂), zirconia (ZrO₂), and alumina (Al₂O₃). An amount of the polishing particles may be 0.1 wt % to 5.0 wt % with respect to the total amount of the polishing slurry. If the polishing particles are included in an amount less than 0.1 wt %, the polishing target film is not sufficiently polished, and if the polishing particles are included in an amount exceeding 5.0 wt %, scratches may occur on the surface of the polishing target film. The average particle diameter of the polishing particles may be 50 nm to 700 nm. For example, if the average particle diameter of the polishing particles is less than 50 nm, the polishing target film is not sufficiently polished, resulting in a low polishing rate, and if the average particle diameter of the polishing particles exceeds 700 nm, scratches may be generated in the polishing target film.

An oxidizer is a substance that increases the polishing rate by oxidizing the surface of a metal film such as a silver (Ag) film or an aluminum (Al) film. The oxidizer may include at least one selected from a group consisting of oxygen (O₂), hydrogen peroxide (H₂O₂), ozone (O₃), PAA(CH₃CO₃H), NaIO₄, H₅IO₆, KIO₄, HOCl, NaCOI, I₂, Cl₂, CuO, PbO₂, MnO₂, HNO₃, KNO₃, F₂, and H₂SO₄. An amount of the oxidizer may be greater than 0 wt % and less than or equal to 5.0 wt % with respect to the total amount of the polishing slurry—for example, 0.01 wt % to 3.0 wt %. The amount of the oxidizer may be 0.01 wt % to 0.1 wt % with respect to the total amount of the polishing slurry. For example, if the amount of the oxidizer exceeds 5.0 wt %, the electrostatic repulsion between the polishing slurry and the polishing target film may increase, thereby decreasing the polishing rate.

The zwitterionic compound is a substance that reduce the electrostatic repulsion between the metal film and the polishing slurry, thereby increasing the polishing rate. The zwitterionic compound may comprise at least one selected from a group consisting of alanine, phenylalanine, proline, glycine, histidine, lysine, arginine, threonine, aspartic acid, tryptophan, glutamine, betaine, cocamidopropyl betaine and lauryl propyl betaine. An amount of the zwitterionic compound may be greater than 0 wt % and less than or equal to 5.0 wt % with respect to the total amount of the polishing slurry—for example, it may be 0.01 wt % to 0.1 wt %. For example, if the amount of the zwitterionic compound exceeds 5.0 wt %, the surface roughness of the polishing target film may increase, thereby decreasing the reflectivity.

The polishing slurry according to an embodiment may further comprise a corrosion inhibitor.

The corrosion inhibitor is a substance that prevent oxidation of the surface of a metal film and reduce surface roughness of the metal film. The corrosion inhibitor may include at least one selected from a group consisting of benzotriazole BTA, dicyclohexylammonium nitrite DAN, triethanolamine TEA, monoethanolamine MEA, and diethanolamine DEA.

An amount of the corrosion inhibitor may be greater than 0 wt % and less than or equal to 5.0 wt % with respect to the total amount of the polishing slurry for example, 0.01 wt % to 0.1 wt %. The amount of the corrosion inhibitor may be less than the amount of the oxidizer or the amount of the zwitterionic compound. For example, if the amount of the corrosion inhibitor exceeds 5.0 wt %, oxidation does not occur easily on the surface of the polishing target film which may reduce the polishing rate.

Polishing particles, oxidizers, zwitterionic compounds and corrosion inhibitors included in the polishing slurry may be contained in a solution. For example, polishing particles, oxidizers, zwitterionic compounds, and corrosion inhibitors may be dispersed and distributed in water, for example deionized DI water.

Additionally, a pH adjustor may be further included in the polishing slurry to adjust the pH of the polishing slurry. The pH adjustor may include at least one selected from a group consisting of HNO₃, NaOH, KOH, and tetramethylammonium hydroxide TMAH.

The pH of the polishing slurry according to an embodiment may be from 3 to 10—for example, 7. The amount of each component included in the polishing slurry is appropriately adjusted.

When a CMP process is performed on the surface of a metal film, such as a silver (Ag) film or an aluminum (Al) film, using the polishing slurry according to the present embodiment, the reflectivity of the surface of the metal film increases. In addition, since the polishing slurry according to the present embodiment has a high polishing rate, the process time may be shortened.

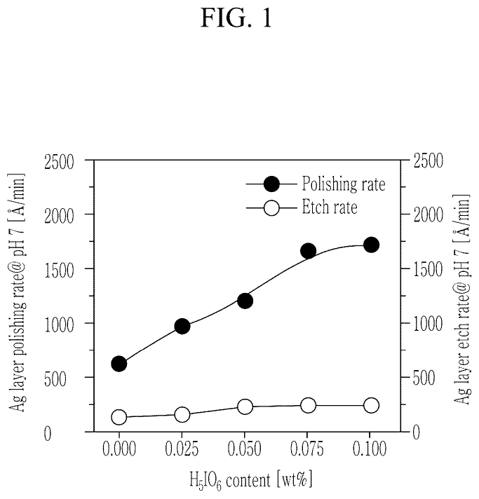

Referring to FIGS. 1 to 3, a polishing rate, an etch rate, and an absorbance reduction of the silver film, and an electrostatic repulsion between the polishing slurry and a silver (Ag) film according to an amount of the oxidizer H₅IO₆ are examined.

The polishing slurries of embodiments 1 to 5 contain 5 wt % silica SiO₂ as polishing particles and an average particle diameter of 130 nm, and 0 wt %, 0.025 wt %, 0.05 wt %, 0.075 wt %, and 0.1 wt % of H₅IO₆ (halide oxidant) as an oxidizer, respectively.

[Table 1] and FIGS. 1 to 3 are experimental data measuring the polishing rate, the etch rate, and the absorbance reduction of the silver film, and the electrostatic repulsion between the polishing slurry and the silver film after performing a CMP process on the surface of the silver film for 1 minute with the polishing slurry.

The polishing rate indicates the degree of polishing when the silver film is chemically and mechanically polished using the polishing slurry and polishing equipment.

The etch rate indicates the degree of polishing when the silver film is chemically polished using the polishing slurry.

The relative electrostatic force between the polishing slurry and the silver film may be derived by measuring the zeta potential of the surface of the silver film and the polishing slurry, respectively, and multiply the two values.

Absorbance reduction indicates the degree of hydroxyl radical (OH) production according to the amount of H₅IO₆. Absorbance reduction refers to the phenomenon of a decrease in the absorption of light at a specific wavelength, and generally occurs when hydroxyl radicals decompose substances such as organic dyes, resulting in a decrease in the absorbance of the dye. The dye may be added to the polishing slurry and its absorbance at a specific wavelength may be measured.

TABLE 1

| | Oxi- | Ag layer | | | |
|---|---|---|---|---|---|
| | dizer | polishing | Ag layer | Electrostatic | Absorbance |
| Embodi- | amount | rate | etch rate | repulsion | reduction |
| ment | [wt %] | [Å/min] | [Å/min] | [a.u.] | [a.u.] |
| 1 | 0 | 620.9 | 124 | 755.6736 | 0.00326 |
| 2 | 0.025 | 962.52 | 132 | 851.76 | 0.01183 |
| 3 | 0.05 | 1195.74 | 186 | 933.72 | 0.02259 |
| 4 | 0.075 | 1164.52 | 198 | 1049.856 | 0.0363 |
| 5 | 0.1 | 1725.36 | 204 | 1165.96 | 0.05514 |

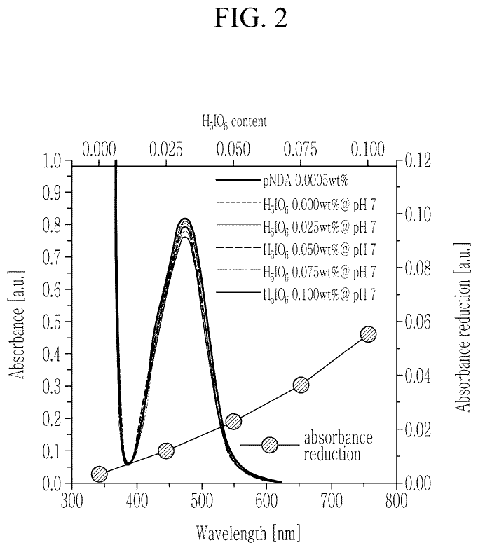

Referring to [Table 1] and FIG. 1, it may be confirmed that the polishing rate and etch rate increase as the amount of H₅IO₆ (halide oxidant) increases. Referring to [Table 1] and FIG. 2, it may be confirmed that as the amount of H₅IO₆ increases from 0 wt % to 0.1 wt %, the absorbance reduction increases from 0.00326 a.u. to 0.05514 a.u. That is, as the amount of H₅IO₆ increases, the amount of hydroxyl radicals generated in the polishing slurry increases, accelerating the oxidation of the surface of the silver film, and thus improving the polishing rate of the silver film.

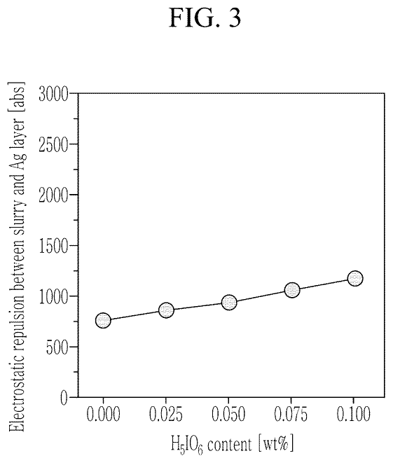

However, referring to [Table 1] and FIG. 3, it may be confirmed that as the amount of H₅IO₆ increases, the electrostatic repulsion between the polishing slurry and the silver film increases. When the amount of H₅IO₆ is higher than 0.1 wt %, the effect of increased electrostatic repulsion may be more dominant than the effect of increased hydroxyl radical production.

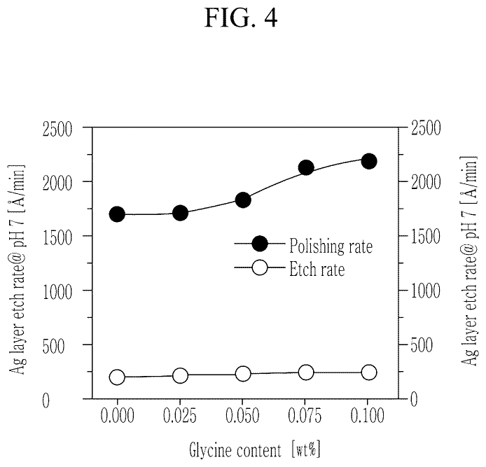

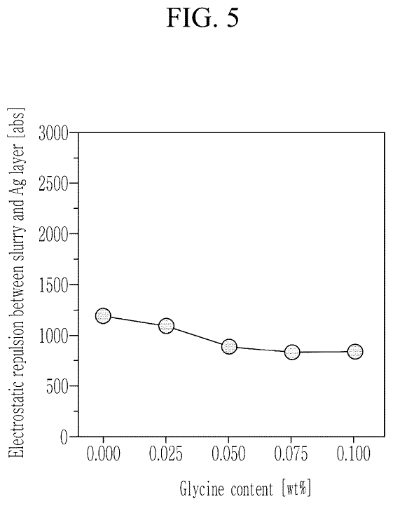

Referring to FIGS. 4 and 5, the polishing rate, the etch rate, and the electrostatic repulsion between the polishing slurry and the silver film according to the amount of the zwitterionic compound (glycine) of the silver (Ag) film are examined.

Referring to [Table 2], the polishing slurries of embodiments 6 to 10 contain 5 wt % of silica SiO₂ as polishing particles and an average particle diameter of 130 nm, 0.1 wt % of H₅IO₆ (halide oxidant) as an oxidizer, and 0 wt %, 0.025 wt %, 0.05 wt %, 0.075 wt %, and 0.1 wt % of glycine as a zwitterionic compound, respectively.

[Table 2] is experimental data measuring the polishing rate, the etch rate, and the electrostatic repulsion between the polishing slurry and the silver film after performing a CMP process on the surface of the silver film for 1 minute with the polishing slurry.

TABLE 2

| | Glycine | Ag layer | Ag layer | Electrostatic |
|---|---|---|---|---|
| | amount | polishing rate | etch rate | repulsion |
| Embodiment | [wt %] | [Å/min] | [Å/min] | [a.u.] |
| 6 | 0 | 1728.36 | 203 | 1165.96 |
| 7 | 0.025 | 1727 | 217 | 1077.12 |
| 8 | 0.05 | 1852 | 231 | 891.8 |
| 9 | 0.075 | 2165 | 235 | 840.16 |
| 10 | 0.1 | 2234 | 241 | 832.128 |

Referring to [Table 2] and FIG. 4, it may be confirmed that as the amount of glycine increases, the polishing rate and etch rate of the silver film increase. Referring to [Table 2] and FIG. 5, it may be confirmed that as the amount of glycine increases from 0 wt % to 0.1 wt %, the relative electrostatic repulsion decreases from 1165.96 a.u. to 832.128 a.u. That is, as the concentration of glycine which is a zwitterionic compound increases, the electrostatic repulsion between the silver film and the polishing slurry decreases, which may increase the polishing rate and etch rate.

However, referring to [Table 2], as the amount of glycine increases from 0 wt % to 0.1 wt %, the etch rate increases from 203 Å/min to 241 Å/min which may increase surface roughness caused by etching.

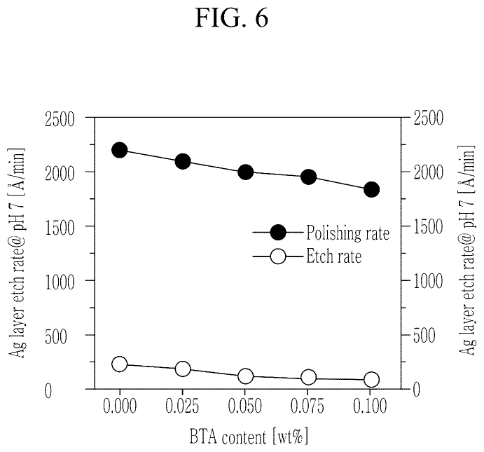

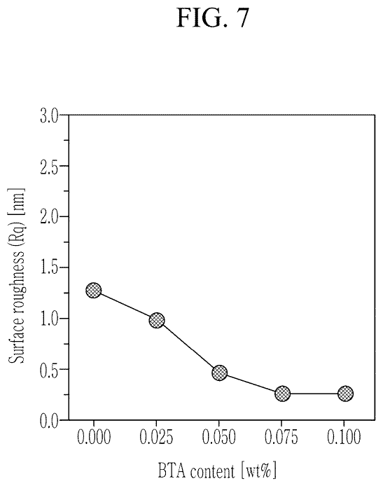

Referring to FIGS. 6 and 7, the polishing rate, etch rate, surface roughness of a silver (Ag) film according to the amount of a corrosion inhibitor are examined.

The polishing slurries of embodiments 11 to 15 contain 5 wt % of silica SiO₂ as polishing particles and an average particle diameter of 130 nm, 0.1 wt of H₅IO₆ (halide oxidant) as an oxidizer, 0.1 wt % of glycine as a zwitterionic compound, and 0 wt %, 0.025 wt %, 0.05 wt %, 0.075 wt %, and 0.1 wt % of benzotriazole BTA as the corrosion inhibitor, respectively.

[Table 3] is experimental data measuring the polishing rate, etch rate, and surface roughness (Rq) of a silver film according to the amount of benzotriazole BTA after performing a CMP process on the silver film for 1 minute with the polishing slurry.

The surface roughness of the silver film may be measured using atomic force microscopy AFM analysis.

The normalized reflectance of the silver film is the relative reflectance measured when the reflectance before the CMP process is set to 100.

TABLE 3

| | | | | Ag layer | |
|---|---|---|---|---|---|
| | | Ag layer | | surface | |
| | BTA | polishing | Ag layer | roughness | Normalized |
| Embodi- | amount | rate | etch rate | (R_{q}) | reflectance |
| ment | [wt %] | [Å/min] | [Å/min] | [nm] | (%) |
| 11 | 0 | 2234 | 241 | 1.263 | 102.319 |
| 12 | 0.025 | 2138 | 186 | 0.997 | 102.345 |
| 13 | 0.05 | 2034 | 123 | 0.483 | 102.387 |
| 14 | 0.075 | 1987 | 112 | 0.217 | 102.397 |
| 15 | 0.1 | 1865 | 96 | 0.192 | 102.398 |

[Table 3] and FIG. 6 show that as the amount of benzotriazole BTA, a corrosion inhibitor, increases from 0 wt % to 0.1 wt %, the etch rate decreases from 241 Å/min to 96 Å/min. Referring to [Table 3] and FIG. 7, it may be confirmed that as the amount of BTA increases from 0 wt % to 0.1 wt %, the surface roughness of the silver film decreases from 1.263 nm to 0.192 nm. That is, as the amount of BTA increases, the surface roughness caused by etching decreases. Therefore, it may be confirmed that the reflectivity of the silver film increases as the amount of BTA increases.

However, it may be confirmed from [Table 3] and FIG. 6 that as the amount of BTA increases from 0 wt % to 0.1 wt %, the polishing rate of the silver film decreases from 2234 Å/min to 1865 Å/min. By adding the amount of BTA of 0.05 wt % or less, a polishing rate of 2000 Å/min or more may be secured.

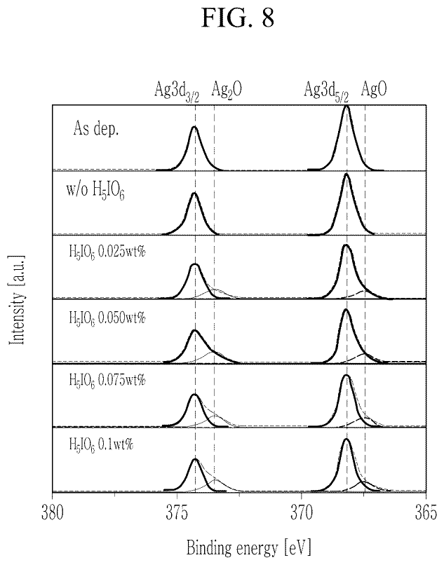

Referring to FIGS. 8 to 11, the degree of formation of an oxide layer on the surface of a silver film according to the amount of the oxidizer is examined.

The polishing slurries of embodiments 16 to 20 contain 5 wt % of silica SiO₂ as polishing particles and an average particle diameter of 130 nm, 0.1 wt % of glycine as a zwitterionic compound, and 0.1 wt % of H₅IO₆ (halide oxidant) as an oxidizer, at 0 wt %, 0.025 wt %, 0.05 wt %, 0.075 wt %, and 0.1 wt %, respectively.

FIGS. 8 to 11 are data measured the degree of formation of a silver oxide layer according to the amount of H₅IO₆ after performing a CMP process on a silver film surface for 1 minute with the polishing slurry.

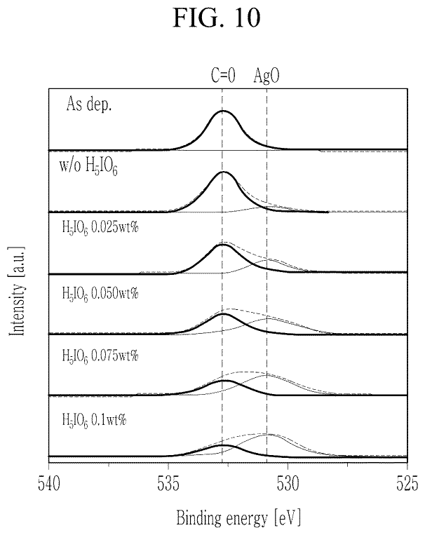

FIGS. 8 and 10 show the results of analyzing the surface components of silver films polished with the polishing slurries of embodiments 16 to 20 using X-ray photoelectron spectroscopy XPS.

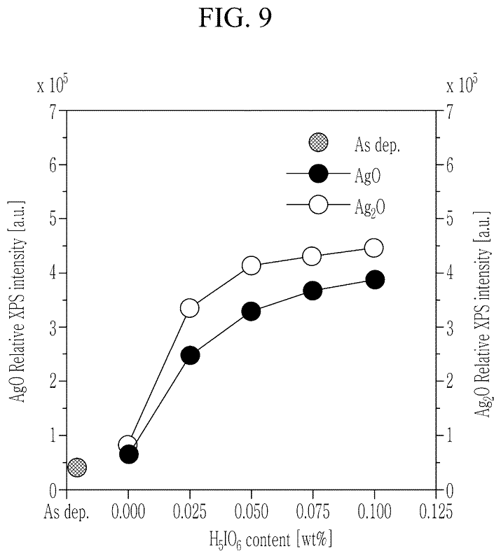

As shown in FIGS. 8 and 9, according to embodiment 16, only Ag 3d_{5/2} and Ag 3d_{3/2} peaks were observed. According to embodiment 16 and embodiment 20, it may be confirmed that as the amount of H₅IO₆ increases, the Ag 3d_{5/2} and Ag 3d_{3/2} peaks decrease, and the AgO and Ag₂O peaks increase. That is, it may be confirmed that the surface of the silver film is oxidized to AgO and Ag₂O by H₅IO₆.

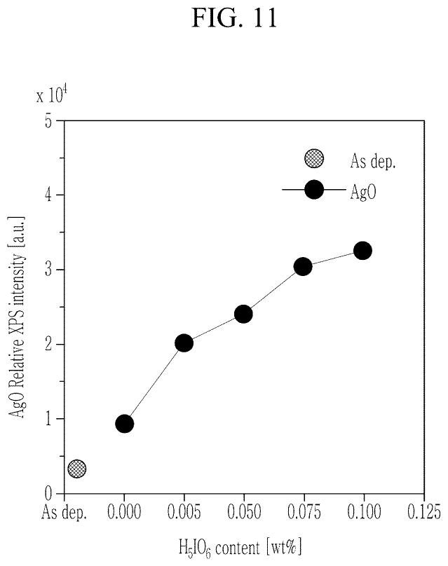

As shown in FIGS. 10 and 11, according to embodiment 16, only the C═O peak was observed. According to embodiment 16 and embodiment 20, it may be confirmed that as the amount of H₅IO₆ increases, the C═O peak decreases and the AgO peak increases rapidly. That is, it may be confirmed that organic material on the surface of the silver film is oxidized by H₅IO₆.

Referring to FIGS. 8 to 11 along with FIG. 3, it may be confirmed that as the amount of H₅IO₆ increases, the amount of hydroxyl radicals generated increases, rapidly increasing the oxidation of silver, and thus the polishing rate may increase.

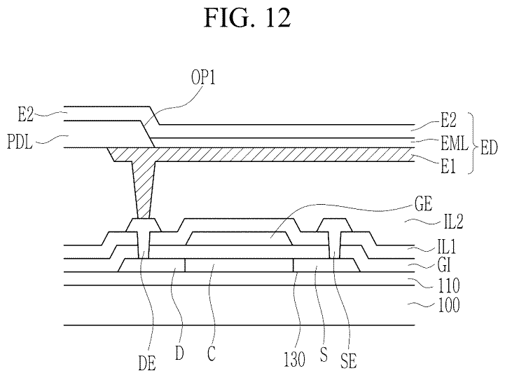

The polishing slurry according to an embodiment may be used in a polishing process of an electrode of a light emitting layer in a manufacturing process of a display device. FIG. 12 is a schematic cross-sectional view of a display area in a display device according to an embodiment.

Referring to FIG. 12, the substrate 100 may include a material having rigid properties such as glass or a flexible material made of a polymer such as plastic or polyimide. According to an embodiment, the substrate 100 may have a single-layer or multi-layer structure including the above materials.

A buffer layer 110 may be positioned on the substrate 100. The buffer layer 110 may include an inorganic material, for example, an inorganic insulating material such as silicon nitride SiNx, silicon oxide SiOx, or silicon nitride SiOxNy. According to an embodiment, the buffer layer 110 may be a single-layer or multi-layer structure including the above inorganic insulating material.

A semiconductor layer 130 may be positioned on the buffer layer 110. The semiconductor layer 130 may include any one of amorphous silicon, polycrystalline silicon, and oxide semiconductor. For example, the semiconductor layer 130 may include low-temperature polysilicon LTPS or an oxide semiconductor material including at least one of zinc (Zn), indium (In), gallium (Ga), and tin (Sn). For example, the semiconductor layer 130 may include indium-gallium-zinc oxide IGZO. The semiconductor layer 130 may include a channel region C, a source region S, and a drain region D that are distinguished depending on whether or not impurity doping is present. The source region S and the drain region D may have conductive properties like the conductor.

A gate insulating layer GI may be positioned on the semiconductor layer 130. A gate insulating layer GI may cover the semiconductor layer 130 and the substrate 100. The gate insulating layer GI may include an inorganic insulating material such as silicon nitride SiNx, silicon oxide SiOx, or silicon oxynitride SiOxNy. The gate insulating layer GI may be a single-layer or multi-layer structure containing the above inorganic insulating materials.

A gate electrode GE may be positioned on a gate insulating layer GI. The gate electrode GE may include a metal or metal alloy such as copper Cu, molybdenum Mo, aluminum Al, silver Ag, chromium Cr, tantalum Ta, or titanium Ti. The gate electrode GE may be composed of a single layer or multiple layers. Among the semiconductor layers 130, the region overlapped with the planar gate electrode GE may be a channel region C.

A first insulating layer IL1 may be positioned on the gate electrode GE. The first insulating layer IL1 may include an inorganic insulating material such as silicon nitride SiNx, silicon oxide SiOx, or silicon oxynitride SiOxNy. The first insulating layer IL1 may be a single-layer or multi-layer structure containing the above inorganic insulating material.

A source electrode SE and a drain electrode DE may be positioned on the first insulating layer IL1. The source electrode SE and the drain electrode DE are respectively connected to the source region S and the drain region D of the semiconductor layer 130 by openings formed in the first insulating layer IL1 and the gate insulating layer GI. Accordingly, the aforementioned semiconductor layer 130, gate electrode GE, source electrode SE, and drain electrode DE form one transistor. In some embodiments, the transistor TFT may include only a source region and a drain region of the semiconductor layer 130 instead of a source electrode SE and a drain electrode DE.

The source electrode SE and drain electrode DE may include a metal or metal alloy such as aluminum (Al), copper (Cu), silver (Ag), gold (Au), platinum (Pt), palladium (Pd), nickel (Ni), molybdenum (Mo), tungsten (W), titanium (Ti), chromium (Cr), or tantalum (Ta). The source electrode SE and the drain electrode DE may be composed of a single layer or multiple layers. According to another embodiment, the source electrode SE and the drain electrode DE may be composed of a triple layer including an upper layer, a middle layer, and a lower layer, and the upper layer and the lower layer may include titanium (Ti), and the middle layer may include aluminum (Al).

A second insulating layer IL2 may be positioned over the source electrode SE and the drain electrode DE. The second insulating layer IL2 may cover the source electrode SE and the drain electrode DE. The second insulating layer IL2 may be a planarization layer which planarizing an uneven surface formed by the transistor, and may be an organic insulating film, and may include one or more materials selected from the group consisting of polyimide, polyamide, acrylic resin, benzocyclobutene, and phenol resin.

A first electrode E1 may be positioned on a second insulating layer IL2. The first electrode E1 is also called an anode electrode and may be composed of a single layer including a transparent conductive oxide film or a metal material or multiple layers including them. The transparent conductive oxide film may include indium tin oxide (ITO), poly-ITO, indium zinc oxide (IZO), indium gallium zinc oxide (IGZO), and indium tin zinc oxide (ITZO). The metal material may include at least one of silver (Ag) and aluminum (Al).

The first electrode E1 according to an embodiment may include a plurality of layers, for example, a triple layer of ITO/Ag/ITO. The polishing slurry according to an embodiment may be used in a CMP process for manufacturing a first electrode E1, and, for example, may be used in a CMP process for manufacturing an Ag film.

The first electrode E1 may be physically and electrically connected to the drain electrode DE through the opening of the second insulating layer IL2. Accordingly, the first electrode E1 may receive an output current to be transmitted from the drain electrode DE to the light emitting layer EML to be described later.

A pixel defining layer PDL and a spacer may be positioned on the first electrode E1 and the second insulating layer IL2. The pixel defining layer PDL includes a pixel opening OP1 that is disposed in an area corresponding to at least a portion of the first electrode E1. The pixel opening OP1 may be disposed in an area corresponding to the center of the first electrode E1. Therefore, the planar size of the pixel opening OP1 may be smaller than the planar size of the first electrode E1. The pixel defining layer PDL may define the formation location of the light emitting layer EML so that the light emitting layer EML may be positioned exclusively on the upper surface of the first electrode EL. The pixel opening OP1 may define the light emitting area of each pixel.

Each of the pixel defining layer PDL and the spacer may be an organic insulating film including one or more materials selected from the group consisting of polyimide, polyamide, acrylic resin, benzocyclobutene, and phenol resin, and according to an embodiment, the pixel defining layer PDL may be formed as a black pixel defining layer (BPDL) including a black pigment.

The light emitting layer EML may be positioned within the pixel opening OP1 defined by the pixel defining layer PDL. The light emitting layer EML may include organic or inorganic materials that emit red, green, blue, or other light. The light emitting layer EML that emits red, green, or blue light may include a low-molecular or high-molecular organic material. In FIG. 12, the light emitting layer EML is illustrated as a single layer, but in reality, auxiliary layers such as an electron injection layer, an electron transport layer, a hole transport layer, and a hole injection layer may also be included above and below the light emitting layer EML, and the hole injection layer and the hole transport layer may be positioned below the light emitting layer EML, and the electron transport layer and the electron injection layer may be positioned above the light emitting layer EML. In some embodiments, the light emitting layer EML may include quantum dots. Quantum dots (hereinafter also referred to as semiconductor nanocrystals) may include a Group II-VI compound, a Group III-V compound, a Group IV-VI compound, a Group IV element or compound, a Group I-III-VI compound, a Group II-III-VI compound, a Group I-II-IV-VI compound, or a combination thereof. The quantum dots may not contain cadmium.

A second electrode E2 may be positioned on the pixel defining layer PDL and the light emitting layer EML. The second electrode E2 is also called a cathode electrode and may be formed of a transparent conductive layer including indium tin oxide (ITO), indium zinc oxide (IZO), indium gallium zinc oxide (IGZO), and indium tin zinc oxide (ITZO). Additionally, the second electrode E2 may have a translucent characteristic, in which case it may form a microcavity together with the first electrode E1. According to the microcavity structure, light of a specific wavelength is emitted upwards depending on the spacing and characteristics between the two electrodes, and as a result, red, green or blue may be displayed.

The first electrode E1, the light emitting layer EML, and the second electrode E2 may form one light emitting element ED.

An encapsulating layer (not shown) may be positioned on the second electrode E2. The encapsulating layer may include at least one inorganic layer and at least one organic layer.

A first electrode E1 polished with the polishing slurry according to an embodiment has low surface roughness and high reflectivity. Therefore, it is easy to reflect light emitted from the light emitting layer EML, thereby increasing the light efficiency of the display device.

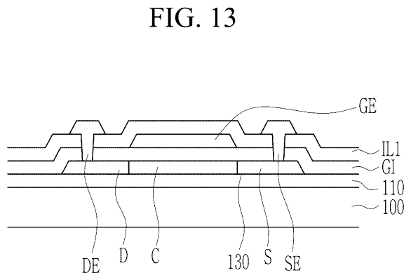

Hereinafter, a method for manufacturing a display device according to an embodiment will be described with reference to FIGS. 13 to 19. FIGS. 13 to 19 are cross-sectional process views sequentially showing a method for manufacturing a display device using a polishing slurry according to an embodiment.

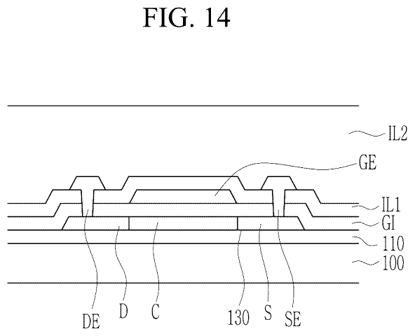

Referring to FIG. 13, a transistor TFT may be formed on a substrate 100. Then, as illustrated in FIG. 14, a second insulating layer IL2 may be formed on the transistor TFT.

Then, the first electrode E1 may be formed by a single-damascene process or a dual-damascene process.

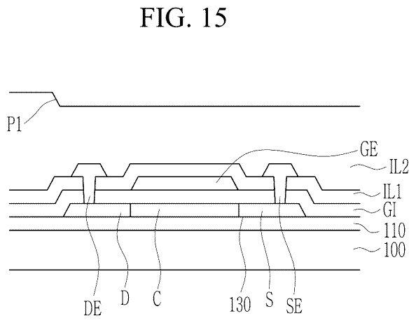

Referring to FIG. 15, a recessed portion P1 may be formed by partially removing a second insulating layer IL2. The recessed portion P1 may be formed, for example, by forming a photoresist pattern as an etching prevention film on an upper surface of the second insulating layer IL2, exposing and developing it, and then partially etching the upper surface of the second insulating layer IL2 using an etchant. Without being limited thereto, the recessed portion P1 may also be formed by a dry etching method using plasma, etc.

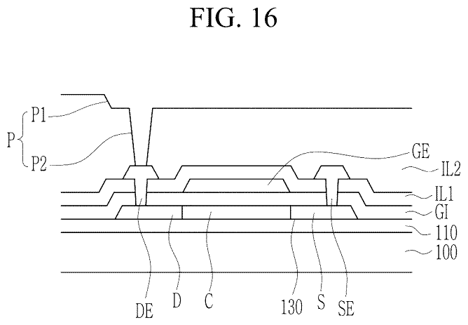

Referring to FIG. 16, a second insulating layer IL2 may be additionally removed to form a contact hole P2 connected to the recessed portion P1. A trench P including the recessed portion P1 and the contact hole P2 may be formed at one time or in multiple steps. For example, the trench P may be formed to expose an upper surface of the drain electrode DE.

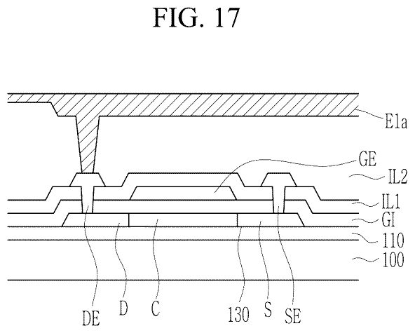

Referring to FIG. 17, a first electrode formation layer Ela may be formed by depositing a metal such as silver (Ag) or aluminum (Al) on a second insulating layer IL2. The first electrode formation layer Ela before the CMP process may have high surface roughness.

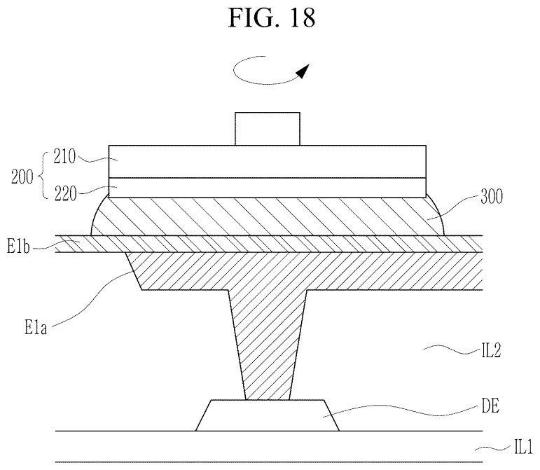

Referring to FIG. 18, a portion E1b of the first electrode formation layer Ela that is not disposed inside the recessed portion P1 may be removed through a CMP process. A polishing slurry 300 according to the present embodiment may be used for the CMP process. The first electrode formation layer Ela may be mechanically and/or chemically polished using a polishing unit 200 and a polishing slurry 300. The polishing unit 200 may include a rotating polishing head 210 and a polishing pad 220 positioned below the polishing head 210 to contact a polishing target. The polishing slurry 300 is provided between the polishing pad 220 and the first electrode formation layer Ela.

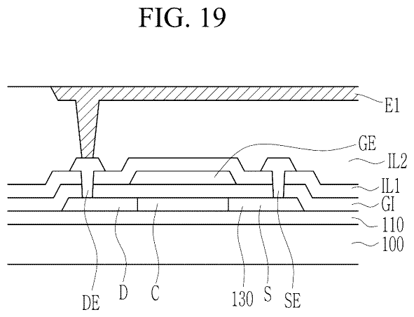

Through this polishing process, a first electrode E1 may be formed as shown in FIG. 19. A display device having a structure similar to that of FIG. 12 may be provided by sequentially forming a pixel defining layer, a light emitting layer, and a second electrode on a first electrode E1.

Since the polishing slurry according to the present embodiment has a high polishing rate, the process time is shortened, thus allowing the CMP process to be efficiently performed. Furthermore, the first electrode polished with the polishing slurry according to the present embodiment has low surface roughness and high reflectivity. Accordingly, the light emitted from the light emitting layer is reflected by the first electrode having high reflectivity and re-emitted to the outside, thereby improving the light efficiency of the display device.

Although the embodiments of the present disclosure have been described in detail above, the scope of the present disclosure is not limited thereto, and various modifications and improvements made by those skilled in the art using the basic concepts of the present disclosure defined in the following claims also fall within the scope of the present disclosure.

What is claimed is:

1. A polishing slurry, comprising:
polishing particles;
an oxidizer; and
a zwitterionic compound.

2. The polishing slurry of claim 1, wherein:
the polishing slurry polishes silver (Ag) or aluminum (Al).

3. The polishing slurry of claim 1, wherein:
the polishing particles contain a silicon compound.

4. The polishing slurry of claim 1, wherein:
the polishing particles comprise at least one selected from a group consisting of silica (SiO₂), ceria (CeO₂), zirconia (ZrO₂), and alumina (Al₂O₃).

5. The polishing slurry of claim 1, wherein:
an amount of the polishing particles is about 0.1 wt % to 5.0 wt % with respect to a total amount of the polishing slurry.

6. The polishing slurry of claim 1, wherein:
an average particle diameter of the polishing particles is about 50 nm to 700 nm.

7. The polishing slurry of claim 1, wherein:
the oxidizer comprises at least one selected from a group consisting of oxygen (O₂), hydrogen peroxide (H₂O₂), ozone (O₃), PAA (CH₃CO₃H), NaIO₄, H₅IO₆, KIO₄, HOCl, NaCOI, I₂, Cl₂, CuO, PbO₂, MnO₂, HNO₃, KNO₃, F₂, and H₂SO₄.

8. The polishing slurry of claim 1, wherein:
an amount of the oxidizer is about 0.01 wt % to 5.0 wt %.

9. The polishing slurry of claim 1, wherein:
a pH is about 3 to 10.

10. The polishing slurry of claim 1, further comprising:
a pH adjuster.

11. The polishing slurry of claim 10, wherein:
the pH adjuster comprises at least one selected from a group consisting of HNO₃, NaOH, KOH, and TMAH (tetramethylammonium hydroxide).

12. The polishing slurry of claim 1, wherein:
the zwitterionic compound comprises at least one selected from a group consisting of alanine, phenylalanine, proline, glycine, histidine, lysine, arginine, threonine, aspartic acid, tryptophan, glutamine, betaine, cocamidopropyl betaine, and lauryl propyl betaine.

13. The polishing slurry of claim 12, wherein:
an amount of the zwitterionic compound is greater than 0 wt % and less than or equal to about 5.0 wt %.

14. The polishing slurry of claim 1, further comprising:
a corrosion inhibitor.

15. The polishing slurry of claim 14, wherein:
the corrosion inhibitor comprises at least one selected from a group consisting of benzotriazole (BTA), dicyclohexylammonium nitrite (DAN), triethanolamine (TEA), monoethanolamine (MEA), and diethanolamine (DEA).

16. The polishing slurry of claim 15, wherein:
an amount of the corrosion inhibitor is greater than 0 wt % and less than or equal to about 5.0 wt %.

17. A method for manufacturing a display device, comprising:
preparing a substrate;
forming a transistor on the substrate;
forming an insulating layer on the transistor;
forming a trench by patterning the insulating layer;
forming a first electrode formation layer by depositing metal in the trench on the insulating layer;
forming a first electrode by polishing the first electrode formation layer using a polishing slurry;
forming a light emitting layer on the first electrode; and
forming a second electrode on the light emitting layer,
wherein the first electrode is electrically connected to the transistor and the polishing slurry comprises polishing particles, an oxidizer and a zwitterionic compound.

18. The method for manufacturing the display device of claim 17, wherein:
the first electrode comprises at least one of silver (Ag) or aluminum (Al).

19. The method for manufacturing the display device of claim 17, wherein:
the polishing slurry further comprises a corrosion inhibitor.

20. The method for manufacturing the display device of claim 17, wherein:
the polishing slurry further comprises a pH adjuster.
